(19) United States
(12) Patent Application Publication
(10) Pub. No.: US 2002/0056885 A1
(43) Pub. Date: May 16, 2002

(54) Semiconductor integrated circuit device

(75) Inventors: Masato Kita, Hachioji (JP); Akihiro Nagatani, Ogose (JP); Hirofumi Watanabe, Tachikawa (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 09/986,611

(22) Filed: Nov. 9, 2001

(30) Foreign Application Priority Data
Nov. 10, 2000 (JP) 2000-342796

(51) Int. Cl. H01L 29/74

(52) U.S. Cl. 257/499; 257/173; 257/355; 257/360

(57) ABSTRACT

This invention realizes high performance of an analog-digital mixed type semiconductor integrated circuit device. A gate lengths (channel lengths) of complementary MISFETs (n-channel MISFETs and p-channel MISFETs) constituting circuit blocks including a digital circuit section, an analog circuit section, and signal input/output sections are different from each other depending on characteristics of the respective circuit blocks. Also, a resistive element of a digital signal input protection circuit and a resistive element of an analog signal input protection circuit are constituted of different materials. Further, digital signal input and output sections and analog signal input and output sections are arranged to be farthest from one another on a semiconductor substrate (chip) 1, thereby providing a chip layout preventing noise of the digital signal input and output sections from entering the analog circuit section.

### TECHNICAL FIELD OF THE INVENTION

The present invention relates to a semiconductor integrated circuit device and particularly relates to a technique effective to be applied to an analog-digital mixed type semiconductor integrated circuit device having an analog circuit section and a digital circuit section formed on the same semiconductor substrate.

### BACKGROUND OF THE INVENTION

Recently, an analog-digital mixed type semiconductor integrated circuit device constituted of insulating gate field effect transistors (to be referred to as “MOSFETs” or “MISFETs” hereinafter) has been used. The inventors of the present invention have been actively involved in the development of analog-digital mixed type semiconductor integrated circuit devices while paying particular attention to the following respects.

(a) To exert an advanced circuit function, an analog circuit section and a digital circuit section are laid out on a semiconductor substrate so as to avoid unnecessary interference therebetween. (b) In an operational amplifier normally used in the analog circuit section, a parasitic element such as an undesired parasitic capacitance is removed as much as possible so as not to decrease the frequency characteristic of a negative feedback circuit comprising an input resistance and a feedback resistance added to the operational amplifier; the irregularity of the resistances of the feedback circuit, the irregularity of the characteristics of a pair of transistors constituting the differential inputs of the operational amplifier, and the irregularity of the characteristics of a pair of transistors constituting an active load circuit such as a current mirror circuit are inhibited to thereby manufacture the operational amplifier without making the amplification factor of the operational amplifier irregular, or a noise signal is reduced. (c) In the analog-digital mixed type semiconductor integrated circuit device, a surge voltage generated in an unexpected transient period breaks down transistors or influences the analog circuit section as noise. The present invention has been made to concretely satisfy these respects.

### SUMMARY OF THE INVENTION

As a technique for preventing the breakdown of the gate of a MOSFET due to a surge input in the analog-digital mixed type semiconductor integrated circuit device, there is known a technique disclosed by Japanese Patent Application Laid-Open No. 9-172146. This publication discloses an analog-digital mixed type semiconductor integrated circuit device wherein a digital circuit section and an analog circuit section have different power source systems (the first potential: Vdd1/Vss1 and the second potential: Vdd2/Vss2). According to this semiconductor integrated circuit device, a protection circuit for making the first power source line and the second power source line conduct to each other when the potential difference between the first power source line (Vdd1/Vss1) of the analog circuit section and the second power source line (Vdd2/Vss2) of the digital circuit section exceeds a predetermined value, is provided between the first and second power source lines, thereby preventing the gate of an MOS transistor constituting an input circuit from being broken down.

Also, Japanese Patent Application Laid-Open No. 8-293598 discloses an analog-digital mixed type semiconductor integrated circuit device wherein the threshold voltage of a MOSFET constituting a digital circuit section is set low, the MOSFET is constituted to set the channel length thereof to have the smallest process dimension, the threshold voltage of a MOSFET constituting an analog circuit section is set high, and the MOSFET is constituted to set the channel length thereof to be larger than the channel length of the MOSFET constituting the digital circuit section.

The Japanese Patent Application Laid-Open No. 9-172146, however, fails to disclose a technique for optimizing the material of a resistive element constituting a part of the protection circuit in accordance with the purpose of the circuit.

Further, the Japanese Patent Application Laid-Open No. 8-293598 fails to disclose a technique for optimizing the channel lengths (gate lengths) of the MOSFETs in each of the digital circuit section and the analog circuit section in accordance with the purpose of the circuit.

It is an object of the present invention to provide a technique for promoting improvement in the performance of an analog-digital mixed type semiconductor integrated circuit device having an analog circuit section and a digital circuit section formed on the same semiconductor substrate.

The above and other objects and novel features of the present invention will be readily apparent from the description and the accompanying drawings of this specification.

Among the inventions disclosed in the present application, the outlines of typical inventions will be briefly described as follows.

The present invention is constituted of one of the following features or a combination thereof:

According to one aspect of the present invention, there is provided an analog-digital mixed type semiconductor integrated circuit device including:

a semiconductor substrate having a main surface;

a digital circuit section formed in a first region of the main surface of the semiconductor substrate;

an analog circuit section formed in a second region of the main surface of the semiconductor substrate;

a digital signal input section for supplying an input signal to the digital circuit section;

a digital signal output section for fetching an output signal from the digital circuit section, wherein the digital signal input section and the digital signal output section are formed in a third region of the main surface of the semiconductor substrate;

an analog signal input section for supplying an input signal to the analog circuit section; and

an analog signal output section for fetching an output signal from the analog circuit section, wherein the analog signal input section and the analog signal output section are formed in a fourth region of the main surface of the semiconductor substrate,

wherein the first region in which the digital circuit section is formed and the second region in which the analog circuit section is formed are arranged to be separate from each other,

wherein the third region in which the digital signal input section and the digital signal output section are formed is arranged to be proximate to the first region,

wherein the fourth region in which the analog signal input section and the analog signal output section are formed is arranged to be proximate to the second region, and

wherein the third region and the fourth region are arranged to be away from each other such that the first region and the second region arranged between the third region and the fourth region.

According to another aspect of the present invention, there is provided an analog-digital mixed type semiconductor integrated circuit device including:

a semiconductor substrate having a main surface;

a digital circuit section constituted to include first complementary MISFETs comprising an n-channel MISFET and a p-channel MISFET and formed in a first region of the main surface of the semiconductor substrate;

an analog circuit section constituted to include second complementary MISFETs comprising an n-channel MISFET and a p-channel MISFET and formed in a second region of the main surface of the semiconductor substrate;

a digital signal input section for supplying an input signal to the digital circuit section;

a digital signal output section for fetching an output signal from the digital circuit section, wherein the digital signal input section and the digital signal output section are formed in a third region of the main surface of the semiconductor substrate;

an analog signal input section for supplying an input signal to the analog circuit section; and

an analog signal output section for fetching an output signal from the analog circuit section, wherein the analog signal input section and the analog signal output section are formed in a fourth region of the main surface of the semiconductor substrate,

wherein a protection circuit for preventing breakdown of the MISFETs of the digital circuit section and the MISFETs of the analog circuit section is constituted to include third complementary MISFETs comprising an n-channel MISFET and a p-channel MISFET formed in the third region and the fourth region, respectively,

wherein the third complementary MISFETs constituting the protection circuit have a first gate length larger than gate lengths of the first complementary MISFETs constituting the digital circuit section,

wherein the second complementary MISFETs constituting the analog circuit section have a second gate length larger than the first gate length.

According to yet another aspect of the present invention, there is provided an analog-digital mixed type semiconductor integrated circuit device including:

a semiconductor substrate having a main surface;

a digital circuit section formed in a first region of the main surface of the semiconductor substrate;

an analog circuit section formed in a second region of the main surface of the semiconductor substrate;

a digital signal input section for supplying an input signal to the digital circuit section;

a digital signal output section for fetching an output signal from the digital circuit section, wherein the digital signal input section and the digital signal output section are formed in a third region of the main surface of the semiconductor substrate;

an analog signal input section for supplying an input signal to the analog circuit section; and

an analog signal output section for fetching an output signal from the analog circuit section, wherein the analog signal input section and the analog signal output section are formed in a fourth region of the main surface of the semiconductor substrate,

wherein the digital signal input section has a first protection circuit for preventing breakdown of the MISFETs of

the digital circuit section, wherein the first protection circuit is constituted to include a first resistive element comprising a semiconductor region partitioned by pn junction in the semiconductor substrate;

wherein one of the analog circuit section and the analog signal input section has a second protection circuit for preventing breakdown of the MISFETs of the analog circuit section,

wherein the second protection circuit is constituted to include a second resistive element comprising a polycrystalline silicon film formed on the main surface of the semiconductor substrate.

### BRIEF DESCRIPTION OF THE DRAWINGS

FIG. 1 is an overall plan view of a semiconductor substrate (chip) showing the circuit configuration of a semiconductor integrated device in one embodiment according to the present invention;

FIG. 2 is a circuit diagram of cells constituting the digital circuit section of the semiconductor integrated circuit device in the embodiment according to the present invention;

FIG. 3 is a circuit diagram of cells constituting the digital circuit section of the semiconductor integrated circuit device in the embodiment according to the present invention;

FIG. 4 is a circuit diagram of cells constituting the digital circuit section of the semiconductor integrated circuit device in the embodiment according to the present invention;

FIG. 5 is a circuit diagram of cells constituting the digital circuit section of the semiconductor integrated circuit device in the embodiment according to the present invention;

FIG. 6 is a circuit diagram of cells constituting the digital circuit section of the semiconductor integrated circuit device in the embodiment according to the present invention;

FIG. 7 is a circuit diagram showing a 4-bit counter circuit of the semiconductor integrated circuit device in the embodiment according to the present invention;

FIG. 8 is a circuit diagram of memory cells constituting a RAM circuit of the semiconductor integrated circuit device in the embodiment according to the present invention;

FIG. 9 is a circuit diagram showing an operational amplifier of the semiconductor integrated circuit device in the embodiment according to the present invention;

FIG. 10 is a circuit diagram showing a switched capacitor circuit of the semiconductor integrated circuit device in the embodiment according to the present invention;

FIG. 11 is a circuit diagram showing the switched capacitor circuit of the semiconductor integrated circuit device in the embodiment according to the present invention;

FIG. 12 is a circuit diagram showing a part (switch) of the switched capacitor circuit of the semiconductor integrated circuit device in the embodiment according to the present invention;

FIG. 13 is a circuit diagram showing the digital signal input section of the semiconductor integrated circuit device in the embodiment according to the present invention;

FIG. 14 is a circuit diagram showing the digital signal output section of the semiconductor integrated circuit device in the embodiment according to the present invention;

FIG. 15 is a circuit diagram showing a protection circuit provided in the digital signal input section shown in FIG. 13;

FIG. 16 is a circuit diagram showing an analog signal input gate protection circuit of the semiconductor integrated circuit device in the embodiment according to the present invention;

FIG. 17 is a plan view showing the chip layout of the circuit blocks of the semiconductor integrated circuit device in the embodiment according to the present invention;

FIG. 18 is a plan view showing the chip layout of the circuit blocks of the semiconductor integrated circuit device in the embodiment according to the present invention;

FIG. 19 is an explanatory view showing a concrete example of the gate lengths of complementary MISFETs constituting the digital circuit section, the analog circuit section, and the signal input/output sections of the semiconductor integrated circuit device in the embodiment according to the present invention;

FIG. 20 is a circuit diagram showing the analog-digital interface section of the semiconductor integrated circuit device in the embodiment according to the present invention;

FIG. 21 is a circuit diagram showing the analog-digital interface section of the semiconductor integrated circuit device in the embodiment according to the present invention;

FIG. 22 is a circuit diagram showing an operational amplifier and a bias circuit of the semiconductor integrated circuit device in the embodiment according to the present invention;

FIG. 23 is a plan view showing the digital signal input section of the semiconductor integrated circuit device in the embodiment according to the present invention;

FIG. 24 shows a cross-sectional view taken along the line A-B and a cross-sectional view taken along the line C-D of FIG. 23;

FIG. 25 is a plan view showing the analog signal gate protection circuit of the semiconductor integrated circuit device in the embodiment according to the present invention;

FIG. 26 shows a cross-sectional view taken along the line A-B and a cross-sectional view taken along the line C-D of FIG. 25; and

FIG. 27 is a circuit diagram showing the differential amplifier of the semiconductor integrated circuit device in the embodiment according to the present invention.

### DETAILED DESCRIPTION OF THE PREFERRED EMBODIMENTS

The embodiment of the present invention will be described hereinafter with reference to the drawings. It is noted that constituent elements having the same functions are denoted by the same reference symbols throughout the drawings for describing the embodiment and no repeated description will be given thereto.

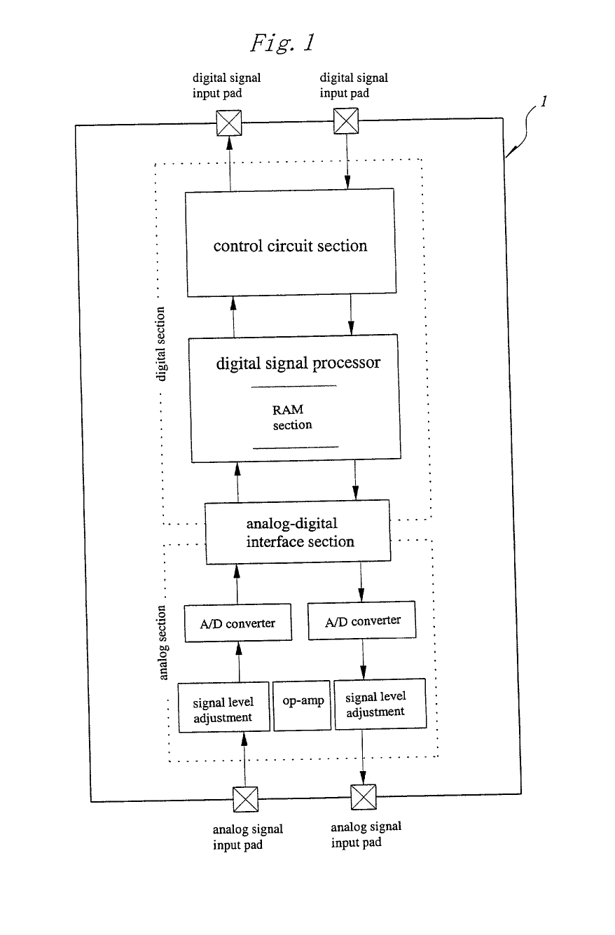

A semiconductor integrated circuit device in this embodiment is an analog-digital mixed LSI wherein an analog circuit section and a digital circuit section are formed on the same semiconductor substrate. FIG. 1 is an overall plan view of the semiconductor substrate (chip) showing the circuit configuration of this LSI.

The analog-digital mixed LSI comprises a digital circuit section formed in a first region on a main surface of the semiconductor substrate (chip) 1, an analog circuit section formed in a second region thereof, a digital signal input section and a digital signal output section both formed in a third region thereof, an analog signal input section and an analog signal output section both formed in the fourth region thereof, and the like. Also, an analog-digital interface section is provided between the digital section and the analog section.

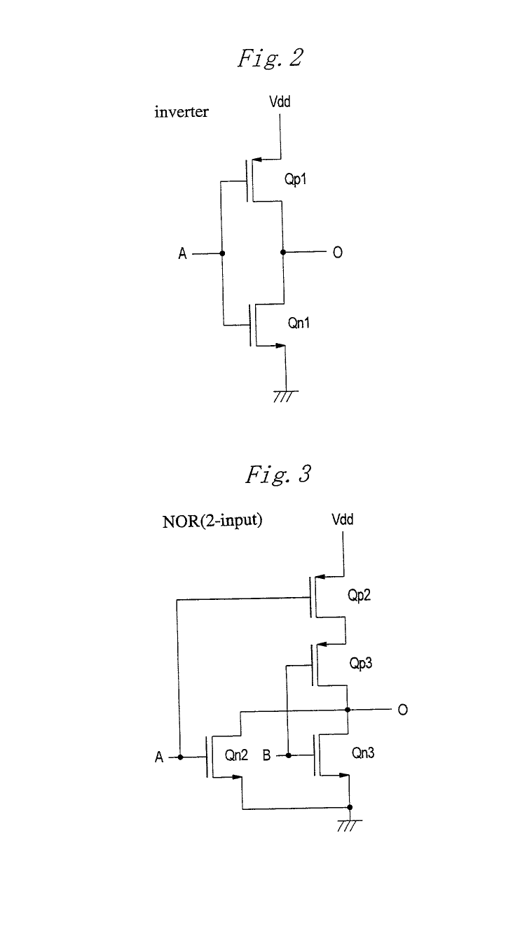

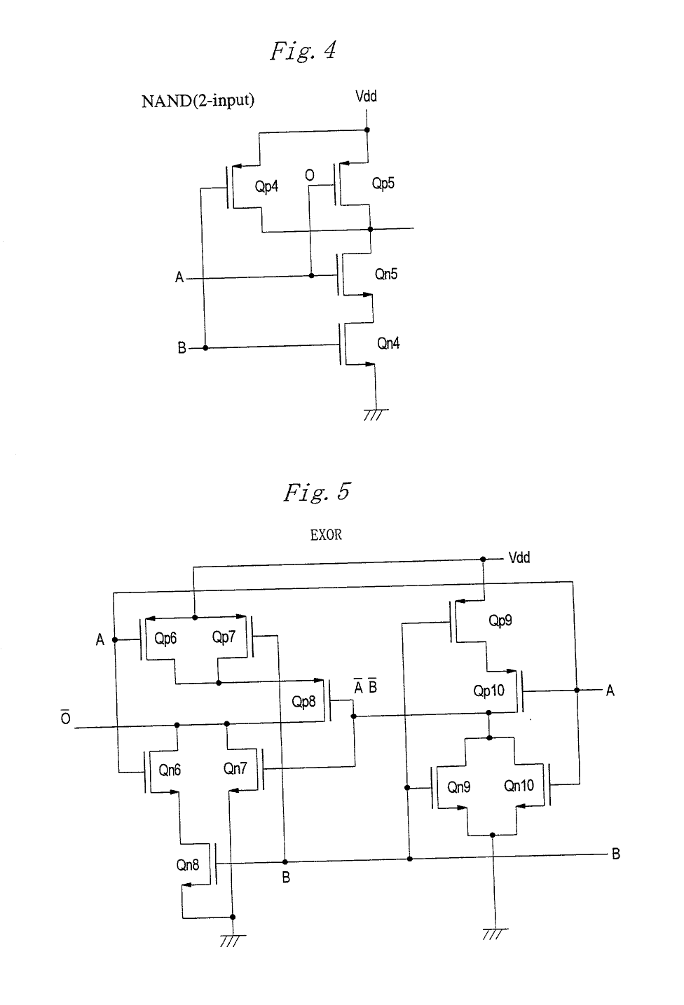

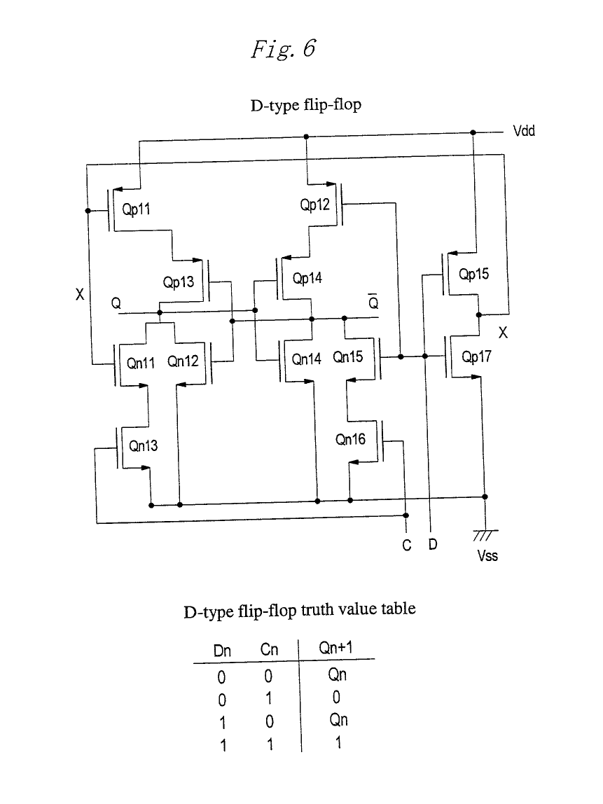

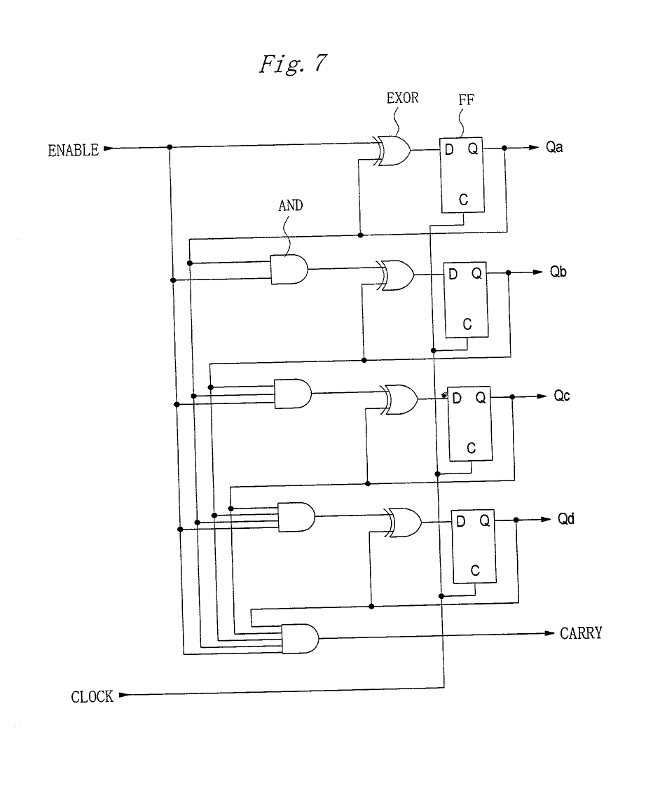

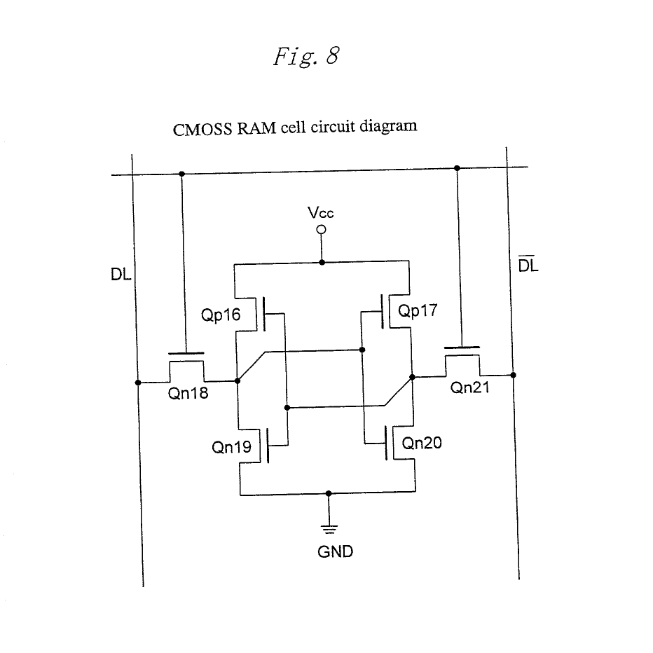

Each of the digital circuit section and the analog circuit section is constituted of complementary MISFETs comprising an n-channel MISFET (Qn) and a p-channel MISFET (Qp). Namely, the digital circuit section has a control circuit and a digital signal processor (DSP) circuit. In this case, the control circuit is constituted of a 4-bit counter circuit as shown in FIG. 7 comprising ANDs, EXORs and FFs, which is realized by using, for example, cells such as inverters, the NORs, the NANDs, the EXORs, and flip-flops shown in FIGS. 2 to 6. In addition, the digital section has a RAM circuit such as an SRAM (static random-access memory) constituted by arranging many memory cells using six MISFETs (Q1 to Q6) in a matrix as shown in FIG. 8 or a ROM (read-only memory) circuit.

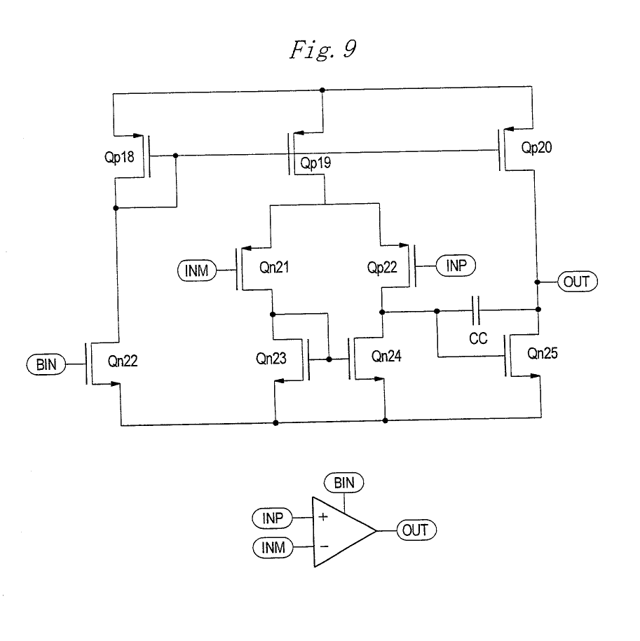

The analog circuit section has an operational amplifier (op-amp). FIG. 9 shows an example of the basic circuit of the operational amplifier. The operational amplifier shown in FIG. 9 is constituted of a differential input amplification stage, and an output amplification stage and a phase compensation capacitance CC, which is feedback-connected from the output of the output amplification stage to the input thereof. The differential input amplification stage comprises a p-channel MISFET Qp19 for constant current, a pair of p-channel MISFETs Qp21 and Qp22 for differential input, and a pair of n-channel MISFETs Qp23 and Qp24 constituting a current mirror load (active load). The output amplification stage comprises an n-channel MISFET Qn25 for output having a gate receiving a signal from the differential input amplification stage by a single end, and a p-channel MISFET Qp20 for constant current functioning as a load thereof.

A bias current circuit, which comprises a diode-connected p-channel MISFET Qp18 and an n-channel MISFET Qn22 for supplying a current to the two p-channel MISFETs Qp19 and Qp20 functioning as constant current sources, is connected to the gates of the p-channel MISFETs Qp19 and Qp20. This bias current circuit is current-mirror connected to the paired constant current p-channel MISFETs Qp19 and Qp20.

What is important for this operational amplifier is to prevent the deterioration of the characteristic of the amplifier due to irregularity in the manufacture of MISFETs, i.e., the deterioration of the pair characteristic of MISFETs so as to prevent the deterioration of circuit performance such as the generation of a noise signal or an offset voltage. That is to say, it is important to improve the pair characteristics of MISFETs so as to prevent irregularity in the gate voltage-drain current characteristics of a pair of p-channel MISFETs Qp21 and Qp22 for differential input, a pair of n-channel MISFETs Qp23 and Qp24 constituting the current mirror load (active load), a pair of p-channel MISFETs Qp19 and Qp20 for constant current, and a MISFET serving as a partner of the p-channel MISFET Qp18 for bias constant current, respectively.

According to the present invention, as will be evident later, the gate lengths of those MISFETs are set larger than those of the other MISFETs constituting the digital circuit section and those of the MISFETs constituting the gate protection circuit so as to ensure the pair characteristics of MISFETs. By so setting, it is possible to decrease irregularity in the current mirror ratios of pairs of MISFETs.

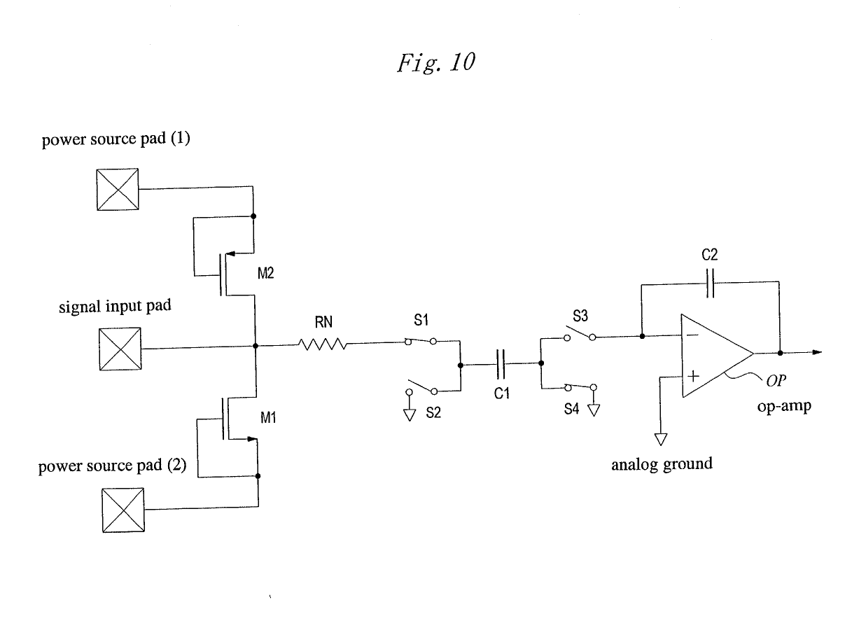

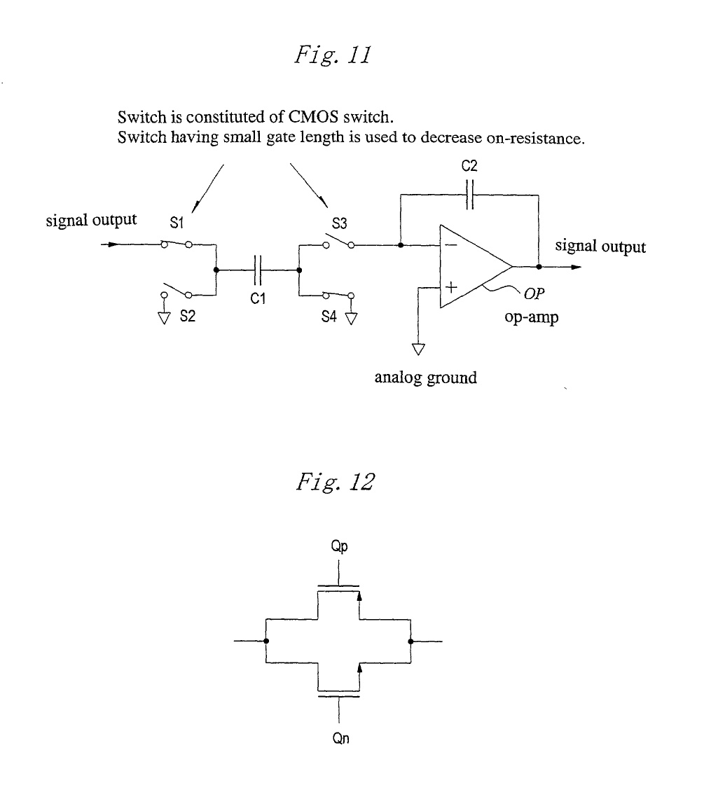

The analog circuit section also has an AC amplifier referred to as “switched capacitance (capacitance feedback type differential amplifier)” as shown in FIGS. 10 to 12 by applying the operational amplifier shown in FIG. 9. In FIGS. 10 and 11, the switched capacitor circuit is constituted of a capacitance feedback circuit, which comprises an operational amplifier OP and capacitances C1 and C2, and switches S1 to S4, each of which comprises p-channel-and n-channel complementary MISFETs shown in FIG. 12. The gain of this AC amplifier or switched capacitance is determined according to the ratio of the capacitance C1 to the capacitance C2.

In FIG. 10, a gate protection circuit, which comprises a p-channel MISFET M2, an n-channel MISFET M1 and a resistance RN which are diode-connected, is connected to an input terminal (pad). This gate protection circuit clamps an abnormal voltage such as a surge input applied to the input terminal in an unexpected transient state to a low voltage, thereby preventing the breakdown of the MISFETs constituting the internal circuits such as the operational amplifier. The gate protection circuit will be described later.

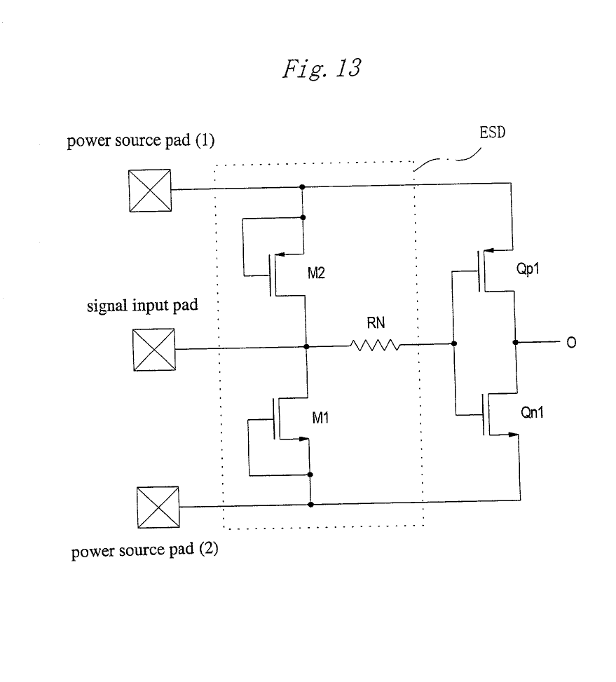

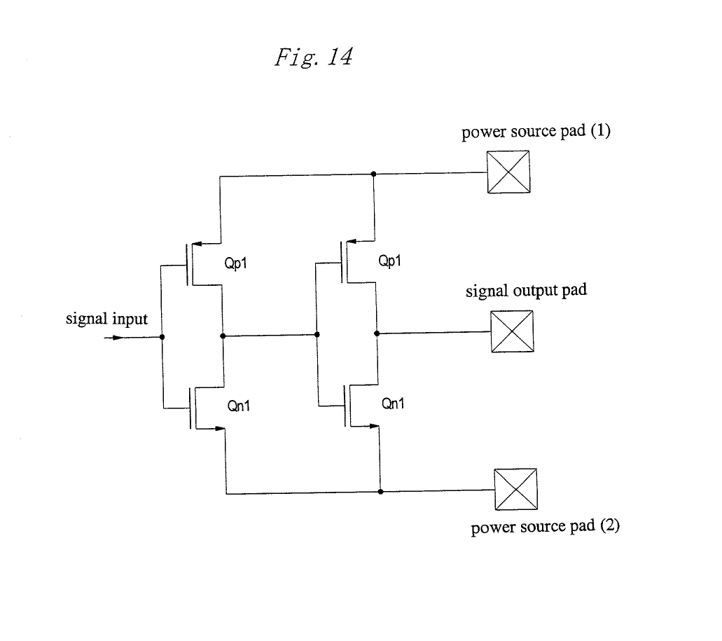

FIG. 13 is a circuit diagram of the digital signal input section including a digital signal input pad (PAD). FIG. 14 is a circuit diagram of the digital signal output section including a digital signal output pad (PAD).

The digital signal input section shown in FIG. 13 has a gate protection circuit ESD comprising a p-channel MISFET M2 and an n-channel MISFET M1 which are diode-connected so as to function as a protection diode, and the protection resistance RN comprising a semiconductor region formed to be partitioned by pn junction in the semiconductor substrate. The digital signal input section also includes an input buffer circuit (inverter) of complementary MISFETs comprising a p-channel MISFET Qp1 and an n-channel MISFET Qn1. The gate protection circuit ESD protects the internal circuits (digital circuit section) from an unexpected surge overcurrent or overvoltage caused by static electricity. On the other hand, the digital signal output section shown in FIG. 14 includes an output circuit (inverter) of complementary MISFETs comprising p-channel MISFETs Qp1 and n-channel MISFETs Qn1, each of which is connected in two stages.

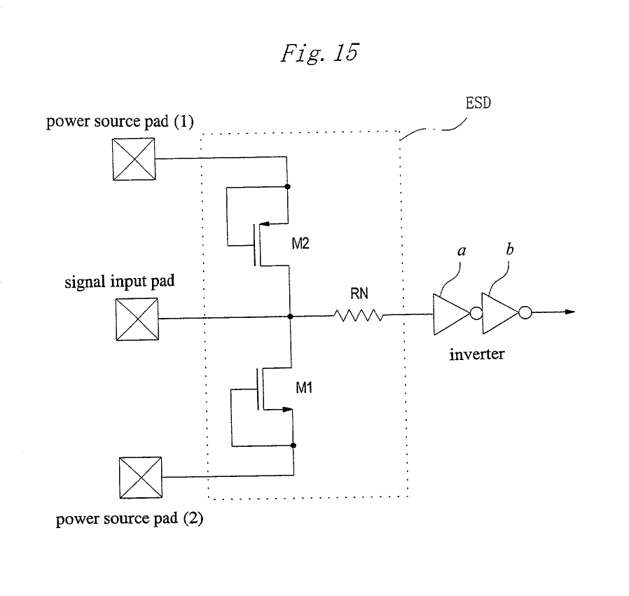

The digital signal input section also has a gate protection (ESD) circuit constituted of a protection diode, which comprises complementary MISFETs (M1 and M2), and a protection resistance (RN) shown in FIG. 15. This gate protection (ESD) circuit protects the internal circuits (digital circuit section) from overcurrent or overvoltage caused by static electricity.

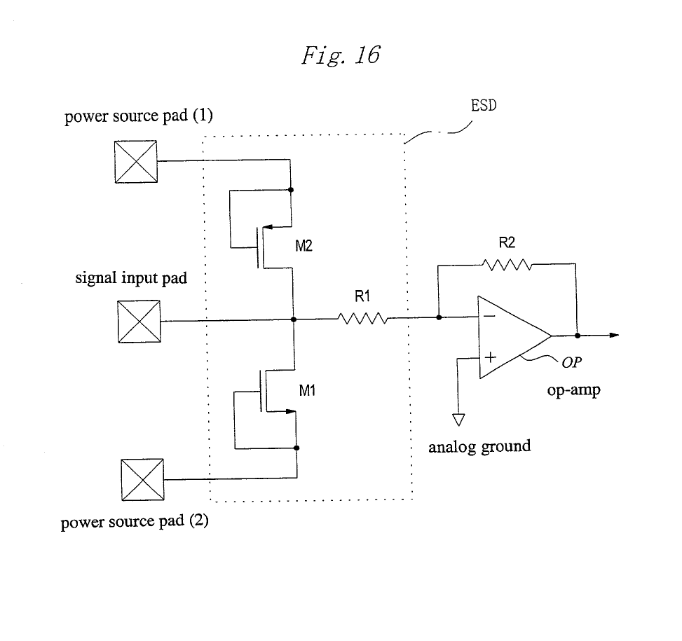

FIG. 16 is a circuit diagram of the analog signal input section including an analog signal input pad and the analog circuit section. The analog signal input section has a protection diode comprising complementary MISFETs (M1 and M2) like in the case of the gate protection (ESD) circuit shown in FIG. 13. The analog circuit section has a gate protection (ESD) circuit constituted of a protection diode having an inversion amplifier comprising resistances (R1, R2) and an operational amplifier, and the protection resistance (R1) serving also as the input resistance of the inversion amplifier, thus protecting the internal circuits (analog circuit section) from overcurrent or overvoltage caused by static electricity.

In FIG. 16, the operational amplifier (op-amp) OP is constituted of the MISFETs shown in FIG. 9. The gain of the inversion amplifier (operational amplifier) is determined according to the resistance ratio (R2/R1) of the negative feedback resistance R2 to the input resistance R1 formed in the analog circuit section. Due to this, it is important to obtain an accurate resistance ratio (R2/R1) so as to attain the uniform gain of the amplifier. As will be described later, according to the present invention, a polycrystalline silicon film formed on the upper portion of an insulating film on the semiconductor substrate is used as the input resistance R1 and the negative feedback resistance R2. In addition, this input resistance R1 is also used as the protection resistance forming the gate protection circuit as already described above.

After the signal level of an analog signal inputted from the analog signal input pad (PAD) is adjusted by a signal level conversion circuit, the analog signal is converted into a digital signal by an A/D converter and fed to the digital circuit section through the analog-digital interface section. Then, the digital signal is processed by the digital signal processor circuit using the RAM or the like and the resultant digital signal is outputted from the digital signal output pad (PAD) through the control circuit.

On the other hand, a digital signal inputted from the digital signal input pad (PAD) is fed from the control circuit of the digital circuit section to the digital signal processor circuit thereof, and further to the analog circuit section through the analog-digital interface section. The digital signal is converted into an analog signal by a D/A conversion circuit and the signal level thereof is adjusted by a signal level conversion circuit. Thereafter, the resultant analog signal is outputted from the analog signal output pad (PAD).

In the case of the analog-digital mixed type LSI stated above wherein the analog circuit section and the digital circuit section are formed on the same semiconductor substrate, it is required to provide an efficient chip layout in which care is taken to prevent the noise of the digital circuit section from entering the analog circuit section and consideration is given to the interfaces of the respective circuit blocks.

As shown in FIG. 1, the digital circuit section and the analog circuit section are arranged to be separate from each other, the digital signal input/output section is arranged to be adjacent to the digital circuit section, and the analog signal input/output section is arranged to be adjacent to the analog circuit section in this embodiment. Also, the digital signal input/output section and the analog signal input/output section are arranged at positions farthest from one another on the semiconductor substrate (chip) 1, thereby providing a chip layout on which the noise of the digital signal input/output section such as a clock terminal and digital signal input and output terminals is prevented from entering the analog circuit section.

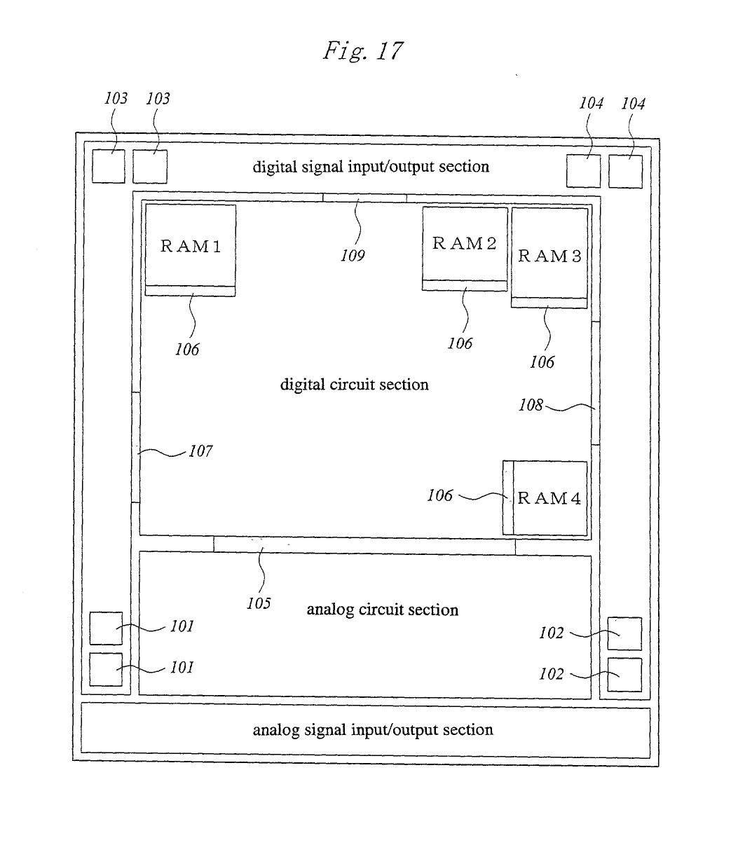

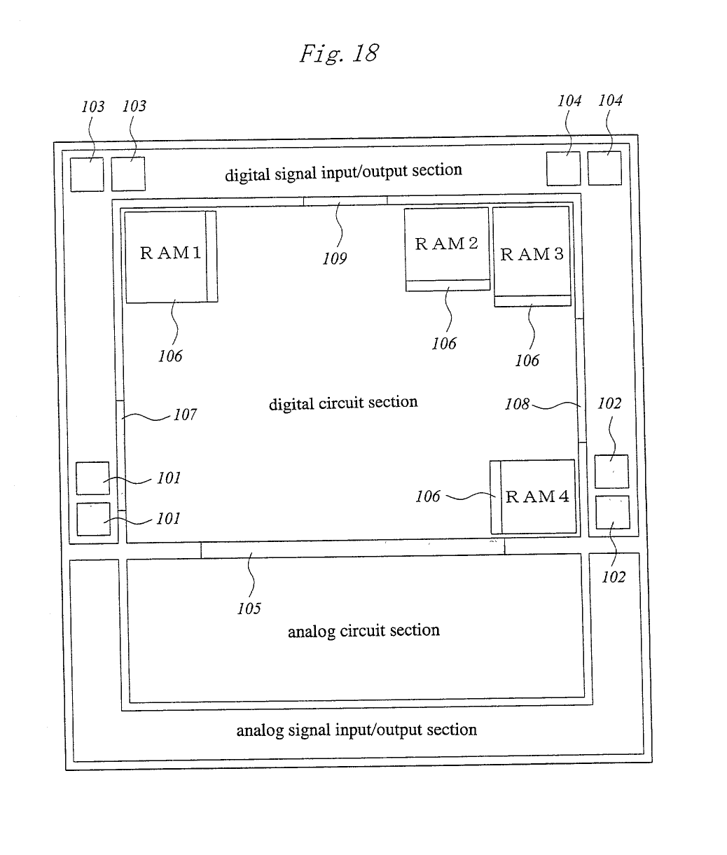

FIGS. 17 and 18 show concrete examples of the chip layout of the respective circuit blocks in this embodiment.

If the input and output pads are arranged on the peripheral portions of the semiconductor substrate (chip) 1, it is important to determine the characteristic of the pad to be arranged in the vicinity of the boundary portion between the digital circuit section and the analog circuit section. As already described above, if the clock terminal which may become a noise source is arranged in the vicinity of the boundary portion, the influence of the noise on the analog circuit section is inevitable.

Considering this, therefore, in this embodiment, in the vicinity of the boundary portion between the digital circuit section and the analog circuit section, pads such as control signal input and output terminals for test, each having a level which is fixed to either a Hi level or a Low level, i.e., which is not changed during ordinary operation, are arranged at positions denoted by reference symbols 101 and 102, and pads such as a clock terminal and a digital signal input terminal, which constantly operate, are arranged away from the analog circuit section as denoted by reference symbols 103 and 104.

Further, as shown in FIGS. 17 and 18, if the analog signal input/output section (pad section) and the analog circuit section are arranged on the lower portions of the semiconductor substrate (chip) 1, the analog-digital interface section 105 is arranged above the analog signal input/output section and the analog circuit section, and the digital circuit section and the digital signal input/output section (pad section) are arranged above the analog-digital interface section 105.

Consider a case where special circuit blocks such as RAM circuits are arranged in the digital circuit section. In this case, if the special circuit blocks are arranged in the corner portions or the peripheral portions of the digital circuit section rather than the central portion thereof with a view of securing interfaces 107 to 109 between the digital circuit section and the digital signal input/output section and the analog-digital interface section 105, the special circuit blocks do not hinder the interface sections 107 to 109 and wiring efficiency is improved compared with a case of arranging the special circuit blocks in the central portion. In that case, if the interfaces 106 of the special circuit blocks are directed toward the center of the digital circuit section, wiring efficiency for laying out the interiors of the digital circuit section by automatic placement and routing is improved.

In addition, according to the analog-digital mixed type semiconductor integrated circuit device (LSI) in this embodiment, the gate lengths (channel lengths) of the complementary MISFETs (n-channel MISFETs and p-channel MISFETs) constituting the above-stated circuit blocks such as the digital circuit section, the analog circuit section, and the signal input/output section are set different depending on the characteristics of the respective circuit blocks.

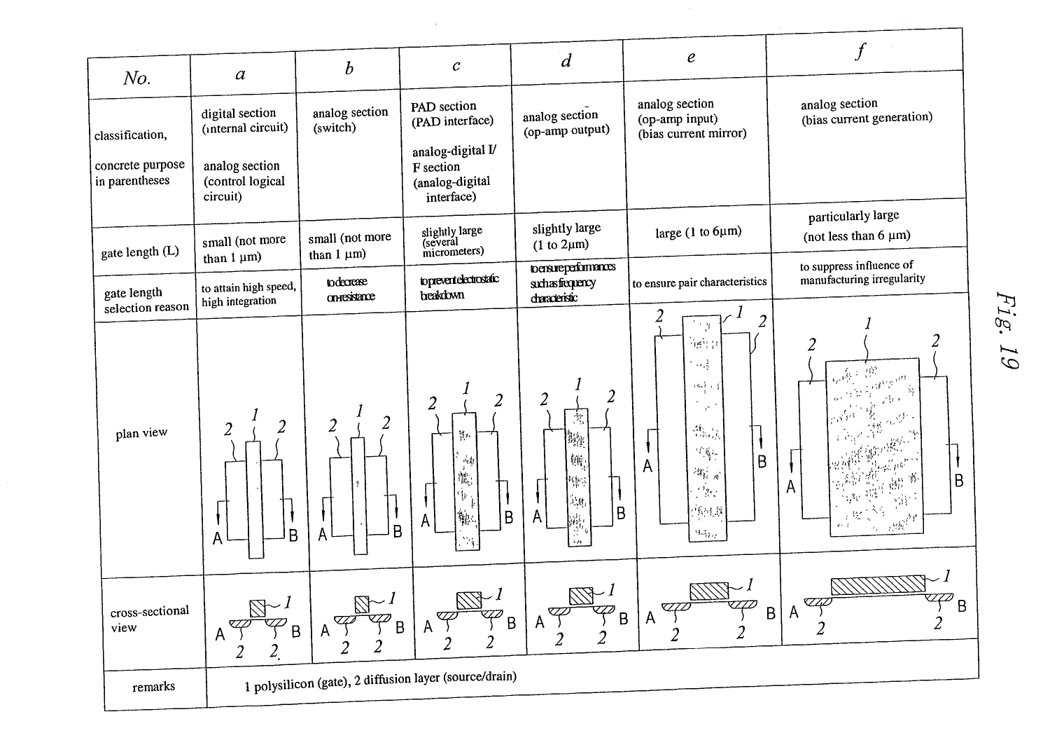

FIG. 19 shows a concrete example of the gate lengths of complementary MISFETs constituting the digital circuit section, the analog circuit section, and the signal input/output sections, respectively.

As shown in the column a of FIG. 19, the complementary MISFETs constituting the digital circuit section (control circuit, digital signal processor circuit and RAM circuit) are constituted to have their respective gate lengths of the smallest process dimensions (e.g., 0.4 μm) so as to realize high speed operation and high integration. For the same reasons, the complementary MISFETs and the like constituting the switched circuit of the analog circuit section have gate lengths of the smallest process dimensions or those close to the smallest process dimensions (e.g., 1.0 μm).

Each switch of the analog circuit section is constituted of complementary MISFETs made by combining an n-channel MISFET and a p-channel MISFET as shown in FIG. 12. As shown in the column b of FIG. 19, the gate lengths of the complementary MISFETs of the switch are not more than 1.0 μm so as to decrease on-resistance generated when the switch is turned on. The switches of this type are used as switches S1 to S4 and the like of the switched capacitor circuit shown in FIG. 11. Based on the relationship of cycles (sampling time) for turning on and off the respective switches, the switches are designed not to cause the time constant between the on-resistance and sampling capacitance C1 to have an adverse influence.

As shown in the column c of FIG. 19, the complementary MISFETs constituting the interface section between the signal input and output pads and the internal circuits have slightly large gate lengths (e.g., several micrometers) so as to prevent electrostatic breakdown. The interface sections of this type involve the inverters (Qp1 and Qp2) of the digital signal input section and the protection diodes (M1 and M2) shown in FIG. 13, the inverters (Qp1 and Qp2) of the digital signal output section shown in FIG. 14 and the like.

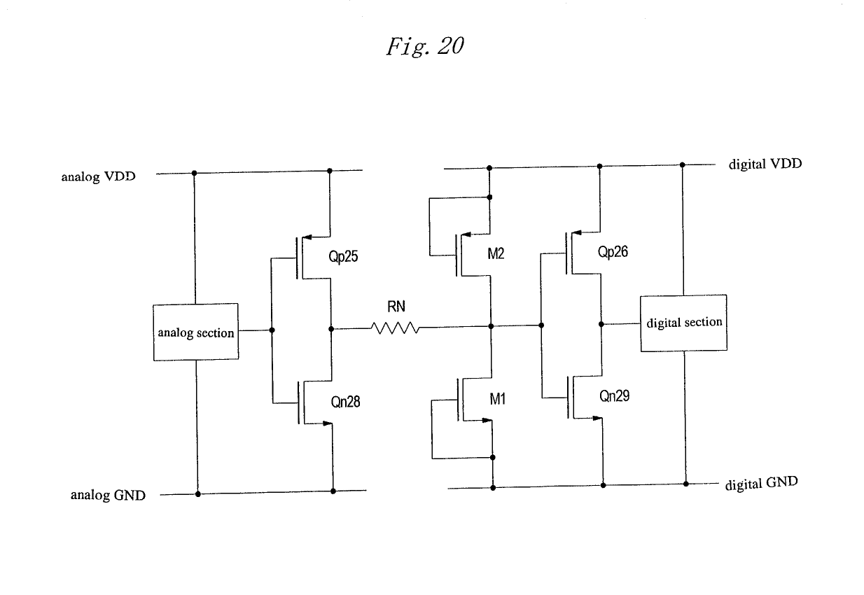

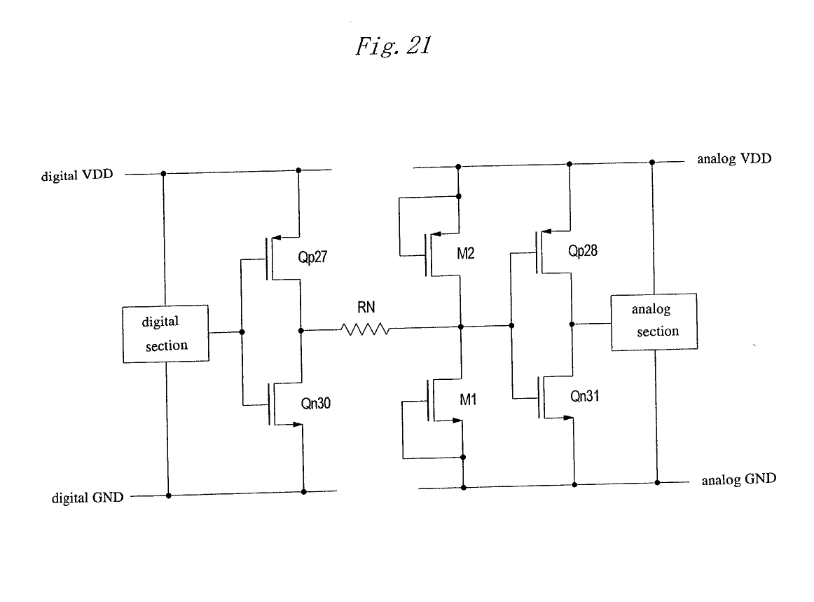

Further, as shown in FIGS. 20 and 21, if the digital circuit section and the analog circuit section have different power source systems, the gate lengths of complementary MISFETs (M1 and M2) or the complimentary MISFETs (Qp25 to Qp28 and Qn28 to Qn3l) of a buffer circuit as a protection diode constituting this interface section are set to be relatively large (e.g., several micrometers) so as to prevent electrostatic breakdown generated in the analog-digital interface section.

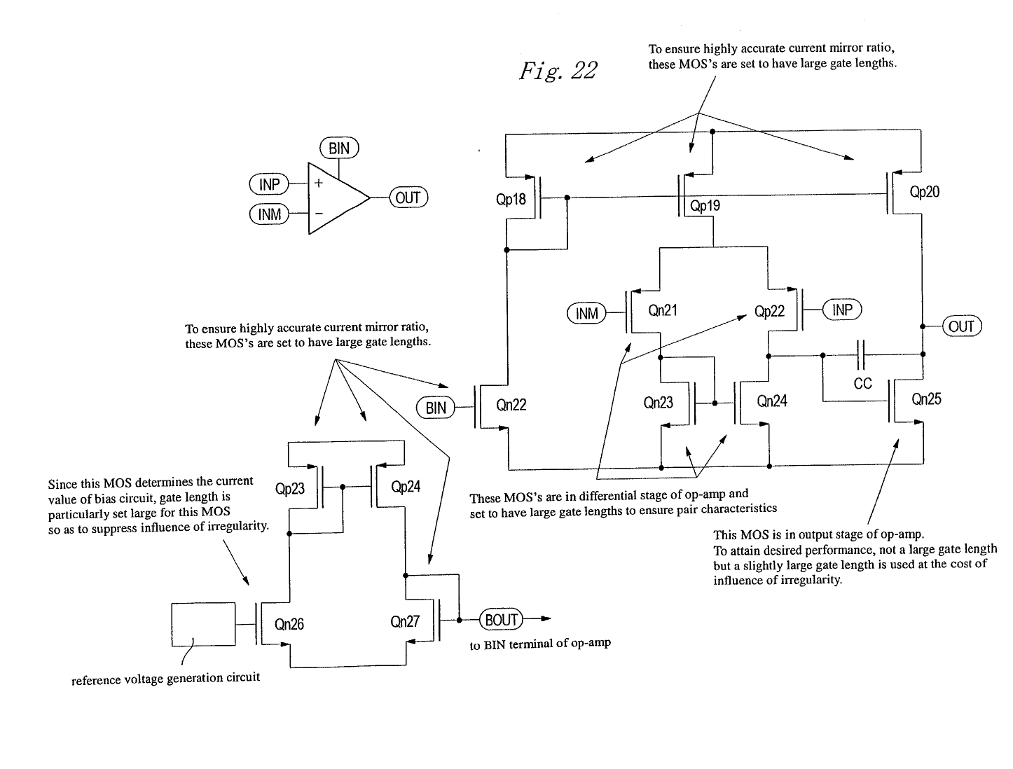

The operational amplifier (op-amp) of the analog circuit section has a circuit configuration as shown in FIG. 9. FIG. 22 shows a circuit configuration in which a bias circuit for generating a bias current is added to the basic circuit of the operational amplifier (op-amp) shown in FIG. 9.

The complementary MISFET (Qn25) constituting the output stage of this operational amplifier is preferably set to have large gate lengths in view of the consistency thereof with the complementary MISFETs (Qn23 and Qn24) for load constituting a part of the differential stage. However, if the gate lengths are too large, the frequency characteristic and output load driving capability of the operational amplifier are disadvantageously deteriorated due to the increase of the gate capacitance of the MISFET (Qn25) in the output stage seen from the differential stage. Due to this, as shown in the column d of FIG. 19, the complementary MISFET (Qn25) constituting the output stage of the operational amplifier is set to have a slightly large gate length (e.g., 1 to 2 μm).

It is necessary that the complementary MISFETs (Qn21, Qn22, Qn23, and Qn24) constituting the differential input stage of the operational amplifier have large gate lengths to decrease process irregularity in gate lengths. This is because it is required to ensure the pair characteristics of the MISFETs (Qn21 and Qn22) for differential inputs and those of the MISFETs (Qn23 and Qn24) for current mirror load. Accordingly, these complementary MISFETs (Qn21, Qn22, Qn23, and Qn24) are set to have large gate lengths (e.g., 1 to 6 μm) as shown in the column e of FIG. 19.

It is also appropriate that the MISFETs (Qn18, Qn19, and Qn2O) used as the current mirror of the operational amplifier and the MISFETs (Qn23, Qn24, and Qn27) used as the current mirror of the bias circuit are set to have large gate lengths (e.g., 1 to 6 μm) since it is required to ensure the pair characteristics of these MISFETs. On the other hand, the MISFET (Qn26) for current supply of the bias circuit is set to have a particularly large gate length (e.g., not less than 6 μm) as shown in the column f of FIG. 19 because the irregular gate length thereof directly causes irregularity in the entire circuit.

Furthermore, according to the analog-digital mixed LSI in this embodiment, the resistive element of the digital signal gate protection circuit and that of the analog signal gate protection circuit are formed of different materials.

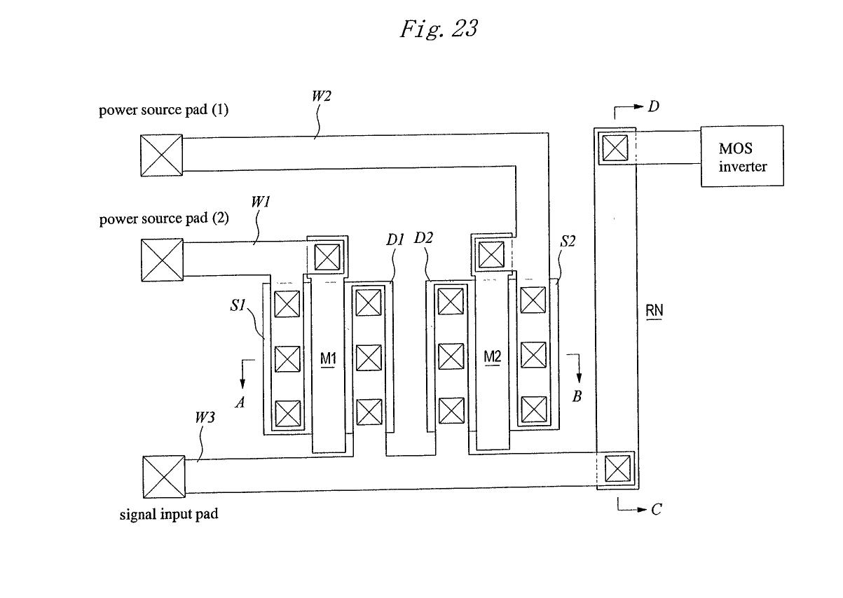

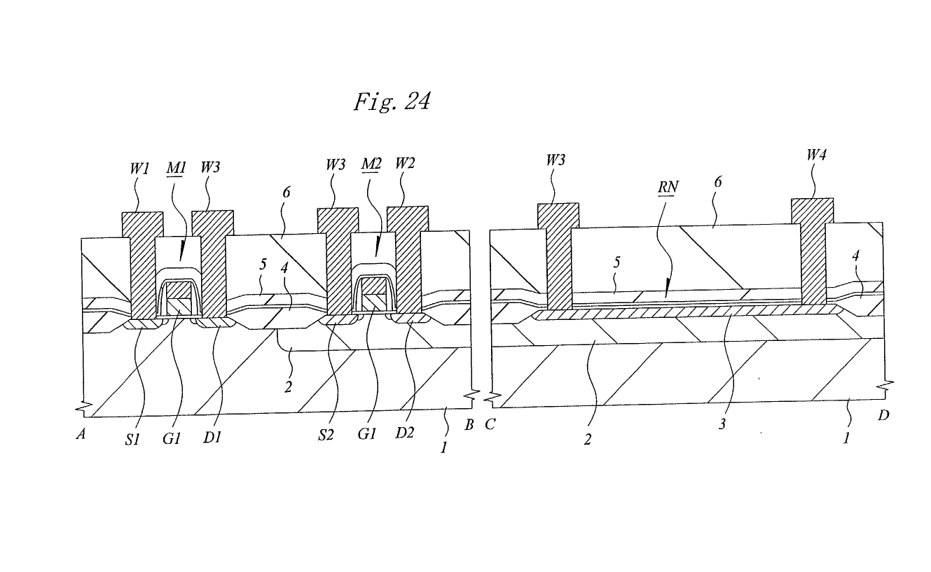

FIG. 23 is a plan view showing the gate protection circuit of the digital signal input section shown in FIG. 15. The left portion of FIG. 24 is a cross-sectional view of the protection diodes (M1 and M2) taken along the line A-B of FIG. 23, and the right portion of FIG. 24 is a cross-sectional view of the protection resistance (RN) taken along the line C-D of FIG. 23.

FIGS. 23 and 24 show an element formation section on the main surface of the semiconductor substrate. On the p-type semiconductor main surface 1 of the semiconductor substrate 1 made of monocrystalline silicon, an isolation silicon oxide film 4 and an n-type well 2 are formed. The protection resistance RN is constituted of a p-type diffusion region 3 partitioned by pn junction in the n-type well 2. This p-type diffusion region 3 (protection resistance RN) can be formed as an opposite conductive type on the p-type main surface 1. Since the parasitic element of the pn junction is added, the p-type diffusion region 3 partitioned by the pn junction functions to clamp an undesired excessive surge input voltage such as an electrostatic input to a lower voltage or functions to decrease the undesired excessive surge input voltage, thereby effectively acting as a protection resistance.

The diode-connected p-channel MISFET M2 has a p-type source region S2 and a p-type drain region D2 formed in the n-type well 2. The MISFET M2 also has a gate electrode G2 comprising a polycrystalline silicon layer as a lower layer and a metal layer of tungsten or the like as an upper layer. The gate electrode G2 and the source region S2 are diode-connected by a wiring (e.g., a metal wiring of aluminum, tungsten or the like) W2 and the drain region D2 is led out by a wiring W3. Likewise, a diode-connected n-channel MISFET M1 has an n-type source region S1 and an n-type drain region D1 formed in the p-type region 1. Similarly to the MISFET M2, the MISFET M1 also has a gate electrode G1 comprising a polycrystalline silicon layer as a lower layer and a metal layer of tungsten or the like as an upper layer. Furthermore, the drain region D1 is led out by a wiring W3 and connected to the drain region of the p-channel diode M2 and one end of the diffusion resistance RN in common. The both diodes M1 and M2 operate as clamp diodes for a surge input voltage. In FIG. 24, reference symbols 5 and 6 denote the lower layer film and the upper layer film of an interlayer insulating film, respectively. The other end of the diffusion resistance RN is electrically connected to the gate electrode of the inverter MISFET by a wiring W4. Consequently, the protection diode circuit (M1, M2 and RN) prevents the breakdown of the gate insulating film of the inverter MISFET due to an excessive surge input voltage.

The complementary MISFETs (M1 and M2) constituting the protection diode shown in FIGS. 23 and 24 are set to have larger gate lengths (e.g., several micrometers) than those of the complementary MISFETs constituting the internal circuits (digital circuit section) in view of the possibility of electrostatic breakdown. Also, the resistance of the analog-digital interface section shown in FIGS. 20 and 21 is constituted of a diffusion resistance, which is resistant to electrostatic breakdown.

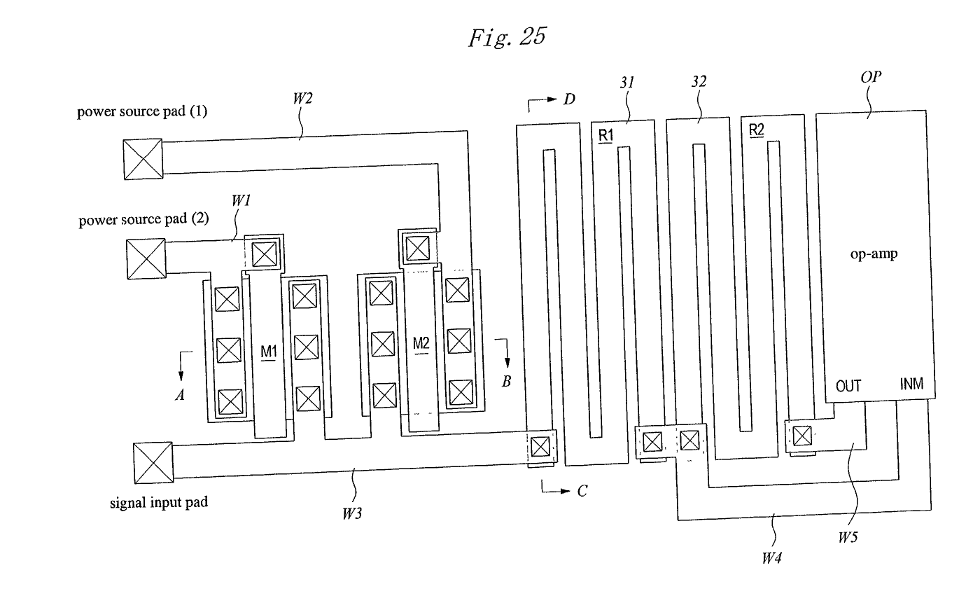

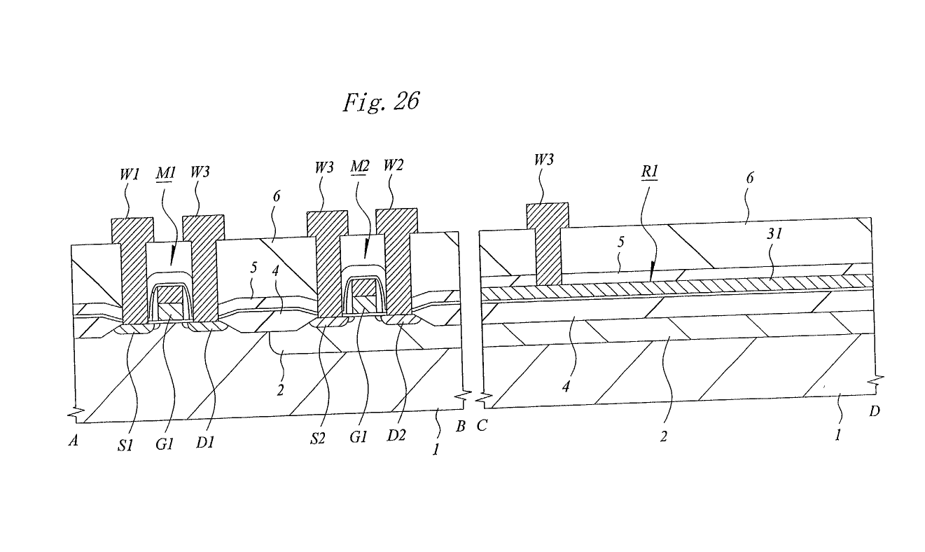

On the other hand, FIG. 25 is a plan view showing the analog signal input gate protection circuit shown in FIG. 16. The left portion of FIG. 26 is a cross-sectional view of the protection diodes (M1 and M2) taken along the line A-B of FIG. 25, and the right portion thereof is a cross-sectional view of the protection resistance R1 taken along the line C-D of FIG. 25.

FIGS. 25 and 26 show an element formation section on the main surface of the semiconductor substrate. On the p-type semiconductor main surface 1 of the semiconductor substrate, an isolation silicon oxide film (thermal oxide film) 4 and an n-type well 2 are formed. The protection resistance R1 constituting the protection circuit ESD is constituted of a polycrystalline silicon film 31 containing p-type or n-type impurities of low concentration formed above the isolation silicon oxide film 4 covering the n-type well 2. This protection resistance R1 also functions as the input resistance of the operational amplifier OP (see FIG. 16). A polycrystalline silicon film 32 similar to the protection resistance (input resistance) R1 is formed above the isolation silicon oxide film 4 although not shown in FIG. 26, thus constituting the feedback resistance R2 of the operation amplifier OP.

The diode-connected p-channel MISFET M2 has a p-type source region S2 and a p-type drain region D2 formed in the n-type well 2 and also a gate electrode G2 comprising a polycrystalline silicon layer as a lower layer and a metal layer of tungsten or the like as an upper layer. The gate electrode G2 and the source region S2 are diode-connected by a metal wiring (e.g., a metal wiring of aluminum, tungsten or the like) W2 and the drain region D2 is led out by a wiring W3.

Likewise, the diode-connected n-channel MISFET M1 has an n-type source region S1 and an n-type drain region D1 formed in the p-type region 1. Similarly to the MISFET M2, the MISFET M1 also has a gate electrode G1 comprising a polycrystalline silicon layer as a lower layer and a metal layer as an upper layer. Further, the gate electrode GI and the source region S1 are diode-connected by the wiring W1 and the drain D1 is led out by the wiring W3 and connected to the drain region of the p-channel diode M2 and one end of the protection resistance R1 in common. The both diodes M1 and M2 operate as clamp diodes for a surge input voltage.

In FIGS. 25 and 26, reference symbols 5 and 6 denote the lower layer film and the upper layer film of an interlayer insulating film, respectively. The other end of the protection resistance R1 is electrically connected to the gate electrode INM of the input MISFET of the operational amplifier OP by a wiring W4. Consequently, the protection diode circuit (M1, M2 and R1) prevents the breakdown of the gate insulating film of the input MISFET of the operational amplifier OP due to an excessive surge input voltage such as static electricity. On the other hand, as shown in FIG. 25, one end of the feedback resistance R2 is electrically connected to the output terminal OUT of the operational amplifier OP by a wiring W5 and the other end thereof is electrically connected to the input terminal INM of the operational amplifier OP by the wiring W4. The feedback resistance R2 constitutes a negative feedback circuit together with the input resistance R1. The gain of the operational amplifier OP is determined according to a resistance ratio (R1/R2).

As shown in FIGS. 25 and 26, the feedback resistance R2 and the protection resistance R1 also serving as the input resistance are constituted of the polycrystalline silicon film formed on the main surface of the semiconductor substrate 1. A combination of the input resistance R1, the feedback resistance R2 and the operational amplifier OP constitute an inversion amplifier. A voltage (analog ground) serving as the reference potential of an analog signal in the analog circuit section is connected to the positive (+) terminal of the operational amplifier OP.

The gain error of the inversion amplifier largely depends on the accuracy of the resistance ration (R2/R1). For that reason, it is possible to realize a highly accurate resistance ratio (R2/R1) if the two resistances (R1 and R2) are formed of the same material such as the polycrystalline silicon film.

It is appropriate to set each resistance used for the inversion amplifier or the like at several tens to several hundreds kΩ in view of the current driving capability of the operational amplifier. If the resistive element having such a resistance value is to be realized by a diffusion resistance, the layout area of the resistive element becomes large, whereby noise from the semiconductor substrate 1 due to the pn junction capacitance may possibly influence the analog circuit section. If the resistances (R1 and R2) are formed of the polycrystalline silicon film, by contrast, it is possible to decrease the influence of noise.

It is noted that another polycrystalline silicon film having a lower sheet resistance than that of the former polycrystalline silicon film is used to form the gate electrodes of the complementary MISFETs (M1 and M2) constituting the semiconductor integrated circuit device in this embodiment. This is because the gate electrodes differ in impurity concentration from the resistances constituted of the former polycrystalline silicon film, e.g., the resistances R1 and R2.

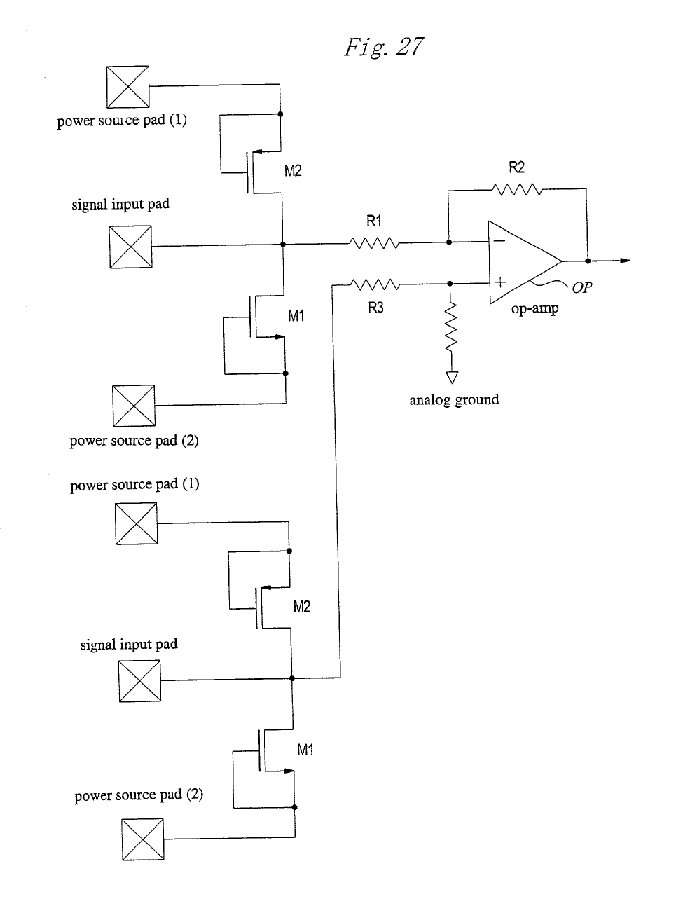

The gain adjusting circuit constituted by combining the resistances and the operational amplifier is exemplified by a differential amplifier shown in FIG. 27 and a non-inversion amplifier besides the above-stated inversion amplifier.

If the circuit less influenced by noise or resistances which cannot be realized by the polycrystalline silicon film are required, in particular, it is possible to employ the diffusion resistances. In the case of, for example, an integrator constituted of resistances and capacitances for which the absolute value of a resistance is important, however, it is more desirable to employ polycrystalline silicon resistances having excellent absolute accuracy. In addition, as already stated above, the input terminal of the operational amplifier is constituted of MISFETs having large gate lengths so as to ensure the pair characteristics of the differential stage.

There are cases where not the polycrystalline silicon resistances but the diffusion resistances are employed even in the analog circuits. For example, the protection resistance RN of the switched capacitor circuit shown in FIG. 11 is a diffusion resistance. In the case of the switched capacitor circuit, if a cycle (sampling type) in which a switch is turned on and off is sufficiently longer than time determined by the time constant between the protection resistance RN and the sampling capacitance C1, the protection resistance formed of a diffusion resistance may possibly be provided between the signal input pad and the input switch S1 without consideration for the absolute value of the resistance.

Furthermore, as already described above, the complementary MISFETs constituting a switch are set to have small gate lengths to decrease on-resistance generated when a switch is turned on. Due to this, the protection resistance RN is preferably constituted of a diffusion resistance, which is resistant to electrostatic breakdown. The resistance value of the protection resistance is several kΩ. Even if the protection resistance is constituted of a diffusion resistance, the layout area of the resistance does not become large to the extent that noise from the semiconductor substrate 1 may possibly influence the analog circuit section.

The present invention made by the inventors of the present invention has been concretely described so far based on the embodiment of the invention. Needless to say, the present invention should not be limited to the above-stated embodiment and various changes and modifications can be made within the scope of the invention.

Among the inventions disclosed in the present application, the advantage obtained by a typical one will be briefly described as follows.

According to the present invention, it is possible to promote improvement in the performance of an analog-digital mixed type semiconductor integrated circuit device.

What is claimed is:

1. An analog-digital mixed type semiconductor integrated circuit device comprising:
a semiconductor substrate having a main surface;
a digital circuit section formed in a first region of the main surface of said semiconductor substrate;
an analog circuit section formed in a second region of the main surface of said semiconductor substrate;
a digital signal input section for supplying an input signal to said digital circuit section;
a digital signal output section for fetching an output signal from said digital circuit section, wherein the digital signal input section and the digital signal output section are formed in a third region of the main surface of said semiconductor substrate;
an analog signal input section for supplying an input signal to said analog circuit section; and
an analog signal output section for fetching an output signal from said analog circuit section, wherein the analog signal input section and the analog signal output section are formed in a fourth region of the main surface of said semiconductor substrate,
wherein said first region in which said digital circuit section is formed and said second region in which said analog circuit section is formed are arranged to be separate from each other,
wherein said third region in which said digital signal input section and said digital signal output section are formed is arranged to be proximate to said first region,
wherein said fourth region in which said analog signal input section and said analog signal output section are formed is arranged to be proximate to said second region, and
wherein said third region and said fourth region are arranged to be away from each other such that said first region and said second region arranged between said third region and said fourth region.

2. The semiconductor integrated circuit device according to claim 1, wherein each of said digital circuit section and said analog circuit section is constituted to include complementary MISFETs comprising an n-channel MISFET and a p-channel MISFET.

3. The semiconductor integrated circuit device according to claim 1, wherein an end portion of said third region extends near said fourth region, and a test pad having a signal input level fixed to one of a High level and a Low level in an ordinary operation state is arranged near a boundary portion between said third region and said fourth region.

4. The semiconductor integrated circuit device according to claim 1, wherein said digital circuit section includes a memory circuit section, and said memory circuit section is arranged in one of a corner portion and a peripheral portion of said first region in which said digital circuit section is formed.

5. The semiconductor integrated circuit device according to claim 4, wherein an interface of said memory circuit section is directed toward a central direction of said first region in which said digital circuit section is formed.

6. An analog-digital mixed type semiconductor integrated circuit device comprising:
a semiconductor substrate having a main surface;
a digital circuit section constituted to include first complementary MISFETs comprising an n-channel MISFET and a p-channel MISFET and formed in a first region of the main surface of said semiconductor substrate;
an analog circuit section constituted to include second complementary MISFETs comprising an n-channel MISFET and a p-channel MISFET and formed in a second region of the main surface of said semiconductor substrate;
a digital signal input section for supplying an input signal to said digital circuit section;
a digital signal output section for fetching an output signal from said digital circuit section, wherein the digital signal input section and the digital signal output section are formed in a third region of the main surface of said semiconductor substrate;
an analog signal input section for supplying an input signal to said analog circuit section; and
an analog signal output section for fetching an output signal from said analog circuit section, wherein the analog signal input section and the analog signal output section are formed in a fourth region of the main surface of said semiconductor substrate,
wherein a protection circuit for preventing breakdown of the MISFETs of said digital circuit section and the MISFETs of said analog circuit section is constituted to include third complementary MISFETs comprising an n-channel MISFET and a p-channel MISFET formed in said third region and said fourth region, respectively,
wherein said third complementary MISFETs constituting said protection circuit have a first gate length larger than gate lengths of said first complementary MISFETs constituting said digital circuit section,
wherein said second complementary MISFETs constituting said analog circuit section have a second gate length larger than said first gate length.

7. The semiconductor integrated circuit device according to claim 6, wherein a gate length of said first complementary MISFETs constituting said digital circuit section is equal to a smallest process dimension.

8. The semiconductor integrated circuit device according to claim 6, wherein said analog circuit section comprises an operational amplifier constituted to include said second complementary MISFETs having said second gate length.

9. The semiconductor integrated circuit device according to claim 6, wherein said analog circuit section further comprises a bias circuit for generating a current supplied to said operational amplifier, wherein said bias circuit is constituted to include said second complementary MISFETs having said second gate length and fourth complementary MISFETs having a third gate length larger than said second gate length.

10. The semiconductor integrated circuit device according to claim 6, wherein said analog circuit section further comprises a switched capacitor circuit, wherein said switched capacitor circuit is constituted to include fifth complementary MISFETs having a fourth gate length smaller than said first gate length.

11. The semiconductor integrated circuit device according to claim 6, wherein said digital circuit section and said analog circuit section have different power source systems, respectively, wherein an analog-digital interface section connecting said digital circuit section to said analog circuit section is constituted to include sixth complementary MISFETs having a gate length almost equal to said first gate length.

12. An analog-digital mixed type semiconductor integrated circuit device comprising:
a semiconductor substrate having a main surface;
a digital circuit section formed in a first region of the main surface of said semiconductor substrate;
an analog circuit section formed in a second region of the main surface of said semiconductor substrate;
a digital signal input section for supplying an input signal to said digital circuit section;
a digital signal output section for fetching an output signal from said digital circuit section, wherein the digital signal input section and the digital signal output section are formed in a third region of the main surface of said semiconductor substrate;
an analog signal input section for supplying an input signal to said analog circuit section; and
an analog signal output section for fetching an output signal from said analog circuit section, wherein the analog signal input section and the analog signal output section are formed in a fourth region of the main surface of said semiconductor substrate,
wherein said digital signal input section has a first protection circuit for preventing breakdown of the MISFETs of said digital circuit section,
wherein said first protection circuit is constituted to include a first resistive element comprising a semiconductor region partitioned by pn junction in said semiconductor substrate,
wherein one of said analog circuit section and said analog signal input section has a second protection circuit for preventing breakdown of the MISFETs of said analog circuit section,
wherein said second protection circuit is constituted to include a second resistive element comprising a polycrystalline silicon film formed on the main surface of said semiconductor substrate.

13. The semiconductor integrated circuit device according to claim 12, wherein said analog circuit section includes an amplifier constituted by connecting said second resistive element to an inversion input of said operational amplifier as an input resistance, and connecting a third resistive element comprising the polycrystalline silicon film formed on the main surface of said semiconductor substrate as a feedback resistance between an inversion input of said operational amplifier and an output terminal of said operational amplifier.

14. The semiconductor integrated circuit device according to claim 12, wherein a third protection circuit constituted to include a fourth resistive element comprising a semiconductor region partitioned by pn junction in said semiconductor substrate, is formed in said analog signal input section,
wherein a switched capacitor circuit connected to said third protection circuit is formed in said analog circuit section.

15. The semiconductor integrated circuit device according to claim 12, wherein said digital circuit section and said analog circuit section have different power source systems, respectively,
wherein an analog-digital interface section connecting said digital circuit section to said analog circuit section is constituted to include a fifth resistive element comprising a semiconductor region partitioned by an pn junction in said semiconductor substrate.

16. The semiconductor integrated circuit device according to claim 12, wherein said analog circuit section further comprises a differential amplifier constituted to include a pair of sixth and seventh resistive elements, which comprise a polycrystalline silicon film formed on the main surface of said semiconductor substrate, and an operational amplifier.
